(19) United States
(12) Patent Application Publication
(10) Pub. No.: US 2001/0027551 A1
(43) Pub. Date: Oct. 4, 2001

(54) CD-ROM decoder

(76) Inventors: Takayuki Suzuki, Gifu-shi (JP); Hiroyuki Tsuda, Ichinomiya-shi (JP); Masayuki Ishibashi, Yao-shi (JP)

Correspondence Address: Douglas W. Swartz, SHERIDAN ROSS P.C., Suite 1200, 1560 Broadway, Denver, CO, 80202-5141, US

(21) Appl. No.: 09/818,149

(22) Filed: Mar. 27, 2001

(30) Foreign Application Priority Data
Mar. 28, 2000 (JP) 2000-088208

(51) Int. Cl. G11C 29/00

(52) U.S. Cl. 714/763

(57) ABSTRACT

A CD-ROM decoder that reduces the load on a microcomputer temporarily stores in a buffer memory in sector units digital data having a predetermined number of bytes and a predetermined format. The CD-ROM also processes the digital data by correcting and detecting code errors included in the digital data. Further, the CD-ROM decoder transfers the processed digital data. The CD-ROM decoder includes a command register for storing a data transfer request command that includes format information of transfer request data and a data transfer circuit connected to the command register. The data transfer circuit decides the format information of the data transfer request command and determines the byte number of the processed digital data that is to be transferred. Further, the data transfer circuit reads the processed digital data from the buffer memory based on the determined byte number and transfers the read processed digital data.

### BACKGROUD OF THE INVENTION

The present invention relates to a CD-ROM decoder, and more particularly, to a CD-ROM decoder for correcting code errors included in digital data and transferring the corrected digital data to a computer.

FIG. 1 is a schematic block diagram of a prior art CD-ROM system 100. The CD-ROM system 100 includes a pickup 2, an analog signal processor 3, a digital signal processor 4, a CD-ROM decoder 5, a buffer RAM 6, and a microcomputer 7.

A spiral record track is defined on the disc 1. Digital data complying with a predetermined format is recorded along the record track. The digital data is generated through eight to fourteen modulation (EFM). The disc 1 is rotated at a constant linear velocity or a constant angular velocity.

The pickup 2 emits a laser beam against the disc 1 and generates from the reflected laser beam a voltage signal corresponding to the digital data recorded on the disc 1.

The analog signal processor 3 shapes the waveform of the voltage signal in correspondence with the fluctuation of the voltage signal provided from the pickup 2 to generate an EFM signal.

The digital signal processor 4 performs EFM demodulation on the EFM signal provided from the analog signal processor 3 to covert the 14-bit digital data to 8-bit digital data and generates CD-ROM data. Further, the digital signal processor 4 uses a cross interleave Reed-Solomon code (CIRC) to detect and correct code errors. A frame is defined by 24 bytes of CD-ROM data. With reference to FIG. 2, a sector is defined by 2,352 (98 frames×24) bytes of CD-ROM data. A synchronization signal (12 bytes) and a header (4 bytes) are allocated to the head of each sector. The synchronization signal has a fixed pattern and indicates the head of each sector. Absolute time information (minutes/seconds/frame number: each 1 byte) and a mode identification code (1 byte) are included in the header. The absolute time information corresponds to an address on the disc 1. The mode identification code is used to identify the format (mode) of the data in a sector. In accordance with the mode and form, user data, an error correction code (ECC), and an error detection code (EDC) are allocated to the 2,336 bytes following the header. For example, referring to FIG. 3, in mode 1, the user data (2,048 bytes), the EDC (4 bytes), ZERO (8 bytes), and the ECC (276 bytes) follow the header. In mode 2 formless, only the user data (2,336 bytes) follows the header. In form 1 of mode 2, a sub-header (8 bytes), user data (2,048 bytes), the EDC (4 bytes), and the ECC (276 bytes) follow the header. In form 2 of mode 2, the sub-header (8 bytes), the user data (2,334 bytes), and the EDC (4 bytes) follow the header.

The CD-ROM decoder 5 also corrects error codes included in the CD-ROM data provided from the digital signal processor 4 and transfers CD-ROM data (user data) to a host computer based on a request from the host computer.

The buffer RAM 6 is connected to the CD-ROM decoder 5 to store CD-ROM data in sector units for a predetermined time. The CD-ROM decoder 5 performs decoding to correct code errors in the CD-ROM data during the predetermined time.

The microcomputer 7 executes a predetermined control program so that the analog signal processor 3, the digital signal processor 4, and the CD-ROM decoder 5 are operated at predetermined timings. In response to a transfer request of the CD-ROM data from the host computer, the microcomputer 7 controls the analog signal processor 3, the digital signal processor 4, and the CD-ROM decoder 5 to transfer the requested data to the host computer.

The microcomputer 7 recognizes or decides flag bits of the transfer request command from the host computer and determines the transfer byte number per sector from the format of the transfer sector. The microcomputer 7 sets the transfer byte number to a predetermined register and controls the transfer of data to the host computer based on the transfer byte number.

Accordingly, in the CD-ROM system 100, the determination of the transfer byte number, which is based on the recognition of the flag bits of the transfer request command from the host computer, and the transfer of data are all performed by the microcomputer 7. Further, the processes described above, including the recognition of the flag bits, are properly performed in accordance with a control program. However, an increase in the operating speed of the CD-ROM system 100 increases the load on the microcomputer 7. As a result, the microcomputer 7 may not be able to follow the operations of the analog signal processor 3, the digital signal processor 4, and the CD-ROM decoder 5.

### SUMMARY OF THE INVENTION

It is an object of the present invention to provide a CD-ROM decoder that decreases the load on the microcomputer, while appropriately performing data transfer control.

To achieve the above object, the present invention provides a CD-ROM decoder for temporarily storing in a buffer memory in sector units digital data having a predetermined number of bytes and a predetermined format, processing the digital data by correcting and detecting code errors included in the digital data, and transferring the processed digital data. The CD-ROM decoder includes a command register for storing a data transfer request command that includes flag bits as format information of transfer request data, and a data transfer circuit connected to the command register for deciding the flag bits of the data transfer request command and determining the byte number of the processed digital data that is to be transferred per sector. The data transfer circuit reads the processed digital data from the buffer memory based on the determined byte number and transfers the read processed digital data.

The present invention also provides a CD-ROM decoder for temporarily storing in a buffer memory in sector units digital data having a predetermined number of bytes and a predetermined format, processing the digital data by correcting and detecting code errors included in the digital data, and transferring the processed digital data. The digital data includes header information and sub-header information. The CD-ROM decoder includes a sector information conversion circuit for deciding the format of the digital data in each sector based on the header information and the sub-header information and generating sector information indicating the decided format. The sector information conversion circuit temporarily stores the sector information in the buffer memory in association with the digital data. A command register stores a data transfer request command that includes flag bits as format information of transfer request data. The transfer request command includes first address information of the buffer memory for the processed digital data that is to be transferred. A sector information decision circuit receives the sector information from the buffer memory and the transfer request command from the command register and compares the sector information to the flag bits of the transfer request command. The sector information decision circuit decides a transfer byte number of the processed digital data that is to be transferred per sector based on the flag bits when the sector information and the flag bits match. An address register stores in sector units second address information of the digital data stored in the buffer memory. A read address generation circuit generates the read address of the digital data stored in the buffer memory based on the determined transfer byte number. A command decision circuit is connected to the address register and the read address generation circuit to compare the first address information of the transfer request command to the second address information stored in the address register and determining based on the comparison whether the processed digital data that is to be transferred is stored in the buffer memory. The command decision circuit sends to the read address generation circuit a command for reading the processed digital data when the digital data that is to be transferred is stored in the buffer memory.

The present invention further provides a method for transferring in sector units digital data having a predetermined number of bytes and a predetermined format with a CD-ROM decoder. The CD-ROM decoder includes a data transfer circuit. The method includes temporarily storing the digital data in a buffer memory, processing the digital data by correcting and detecting code errors included in the digital data, storing a data transfer request command that includes format information of transfer request data in a command register, and deciding the format information of the data transfer request command and determining the byte number of the processed digital data that is to be transferred per sector with the data transfer circuit, reading the processed digital data from the buffer memory based on the determined byte number, and transferring the read processed digital data with the data transfer circuit.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic block diagram of a prior art CD-ROM system;

FIG. 2 is a diagram illustrating the structure of a sector of CD-ROM data;

FIG. 3 is a diagram illustrating formats of a sector of CD-ROM data;

FIG. 4A and FIG. 4B are schematic block diagrams of a CD-ROM decoder according to a preferred embodiment of the present invention;

FIG. 5 is a schematic diagram illustrating the memory area of a buffer RAM;

FIG. 6 is a diagram illustrating the structure of a transfer request command;

FIG. 7 is a flowchart illustrating the determination of a sector type in the CD-ROM decoder of FIGS. 4A and 4B;

FIG. 8 is a table used during a sub-header comparison process;

FIG. 9 is a table showing the relationship between the sector format and sector information; and

FIG. 10 is a flowchart illustrating an automatic data transfer process performed by the CD-ROM decoder of FIGS. 4A and 4B.

### DETAILED DESCRIPTION OF THE PREFERRED EMBODIMENTS

In the drawings, like numerals are used for like elements throughout.

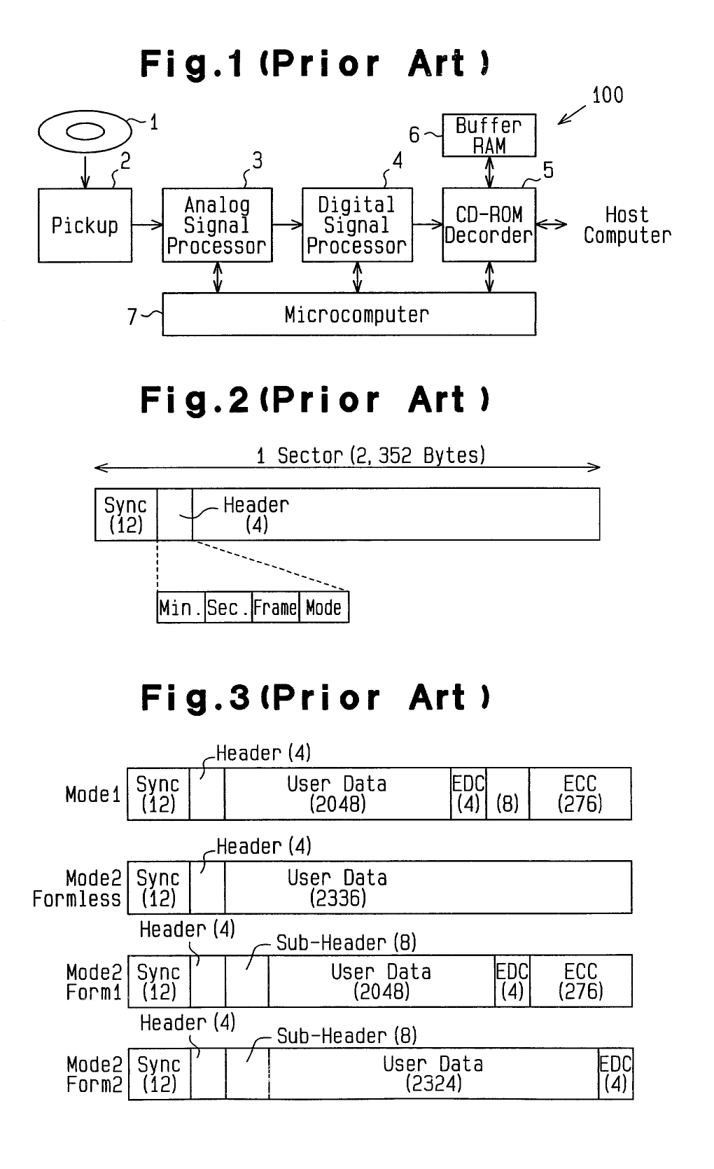

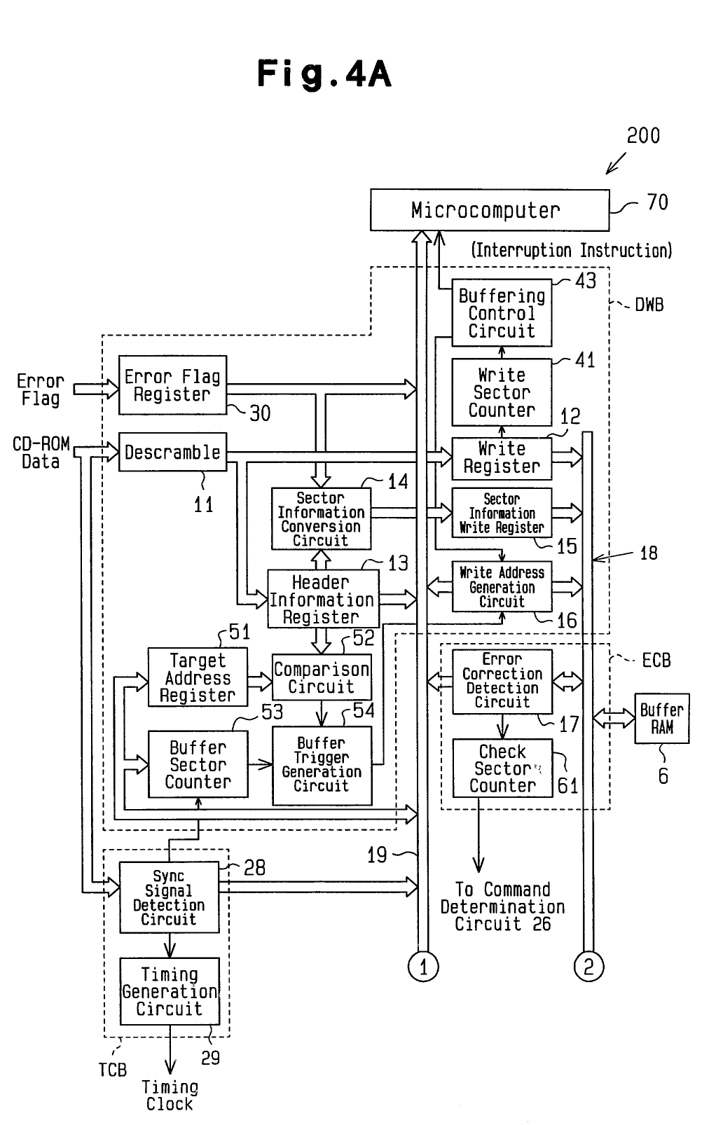

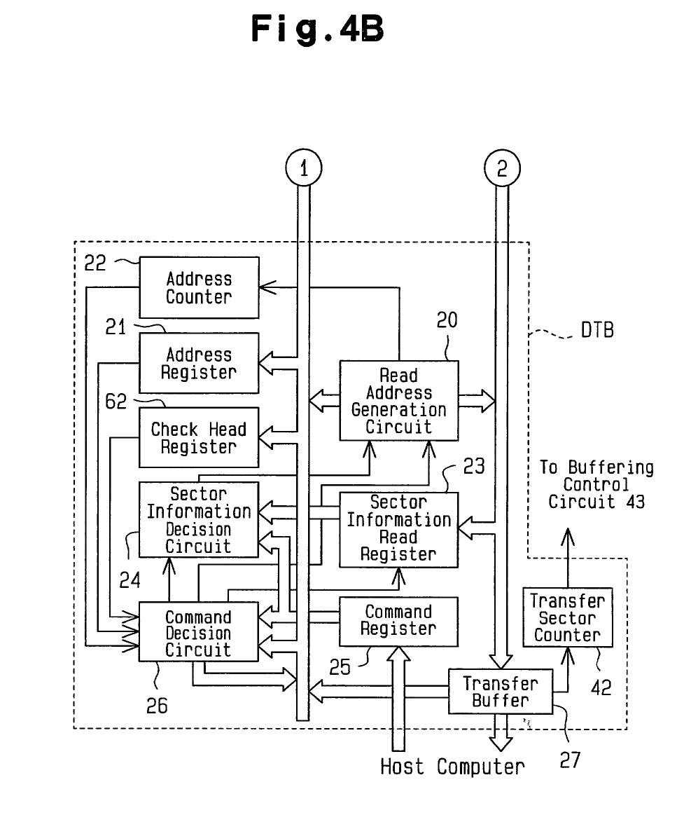

FIGS. 4A and 4B show a CD-ROM decoder 200 according to a first embodiment of the present invention. The CD-ROM decoder 200 is used in lieu of the CD-ROM decoder 5 of FIG. 1 and connected to the buffer RAM 6 and a microcomputer 70.

The CD-ROM decoder 200 includes a data write circuit DWB, an error check circuit ECB, a data transfer circuit DTB, and a timing adjustment circuit TCB. The data write circuit DWB stores CD-ROM data in the buffer RAM 6. The error check circuit ECB detects and corrects write data errors. The data transfer circuit DTB transfers the data stored in the buffer RAM 6 to a host computer. The timing adjustment circuit TCB adjusts the timing of the data write circuit DWB, the error check circuit ECB, and the data transfer circuit DTB.

The data write circuit DWB includes a descramble circuit 11, a write register 12, a header information register 13, a sector information conversion circuit 14, a sector information write register 15, a write address generation circuit 16, an error flag register 30, a write sector counter 41, a buffering control circuit 43, a target address register 51, a comparison circuit 52, a buffer sector counter 53, and a buffer trigger generation circuit 54.

Except for the 12 bytes of the synchronization signal, the descramble circuit 11 descrambles the 2,340 bytes of data in each sector of CD-ROM data. The descramble circuit 11 then generates descrambled CD-ROM data having a predetermined format.

The write register 12 receives CD-ROM data from the descramble circuit 11 and writes the CD-ROM data to the buffer RAM 6 via a first data bus 18. The write register 12 is connected to the write sector counter 41. The write sector counter 41 counts the number of sectors in the CD-ROM data written to the buffer RAM 6 and provides a count value CB to the buffering control circuit 43.

The buffering control circuit 43 performs buffering management based on the count value CB and a count value CT of a transfer sector counter 42.

The header information register 13 extracts 4-byte header information from the CD-ROM data provided by the descramble circuit 11 and transfers the header information to the microcomputer 70 via a second data bus 19. The header information register 13 extracts 8 bytes of data following the header as a sub-header and provides the header and the sub-header to the sector information conversion circuit 14.

The sector information conversion circuit 14 determines the mode of the CD-ROM data based on the header information. When the CD-ROM data is in mode 2, the sector information conversion circuit 14 determines the form based on the sub-header information. In accordance with the determination result, the sector information conversion circuit 14 generates 3 bits of sector information indicating the format of the CD-ROM data in each sector and provides the sector information to the sector information write register 15.

The sector information write register 15 receives the sector information from the sector information conversion circuit 14 and writes the sector information to the buffer RAM 6 via the first data bus 18.

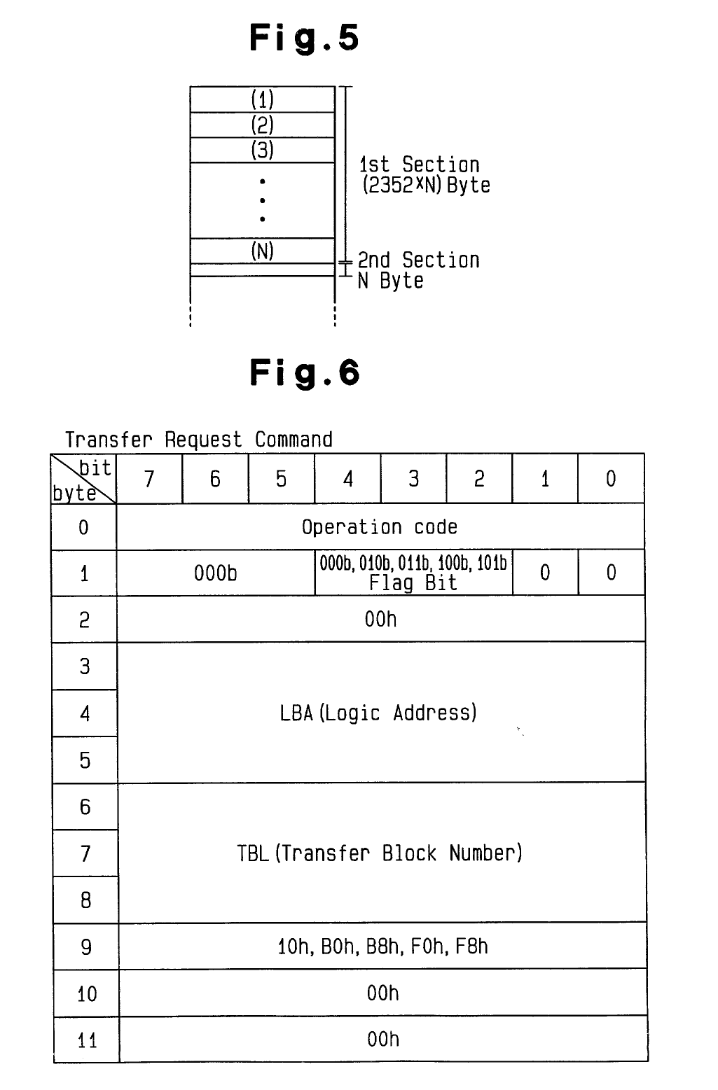

The buffer RAM 6 has sufficient capacity for storing CD-ROM data having a predetermined number of sectors to transfer data to the host computer. Referring to FIG. 5, the buffer RAM 6 has first sections, which store 2,352×N bytes of CD-ROM data, and second sections following the associated first sections to store N bytes of sector information. This associates the CD-ROM data and the sector information (the format information of data) in sector units in the buffer RAM 6.

The write address generation circuit 16 generates an address designating the area for a sector in one of the first sections of the buffer RAM 6 and designates a write address in the buffer RAM 6 for the CD-ROM data stored in the write register 12. The write address, which includes an address corresponding to data at the head of a sector, is provided from the write address generation circuit 16 to an address register 21 via the second data bus 19. Simultaneously, the write address generation circuit 16 generates an address designating an area having one byte in the second sections of the buffer RAM 6 and designates the write address for writing the sector information stored in the sector information write register 15 to the buffer RAM 6. The sector information write address is provided to the address register 21.

The error flag register 30 receives an error flag indicating that an error was not corrected during the error correction process and transfers the error flag to the microcomputer 70 via the second data bus 19. The error flag of the sub-header is also provided to the sector information conversion circuit 14.

A target address register 51 stores target address information provided from a microcomputer 70 via the second data bus 19 and repetitively provides the target address information to the comparison circuit 52. The target address information indicates the address of the sector at the head of the CD-ROM data requested from the host computer and is generated by the microcomputer 70 in response to an instruction from the host computer.

The comparison circuit 52 compares the target address information provided from the target address register 51 with the data address information provided from a header information register 13 to generate a buffering start pulse signal when the two pieces of information match.

The buffer sector counter 53 receives buffering sector information from the microcomputer 70 as preset data. The buffering sector information indicates the number of sectors that are to be buffered (transferred) and is generated in response to an instruction from the host computer. The buffer sector counter 53 counts downward whenever a sector of the CD-ROM data is provided in response to a timing signal, which is provided by a synchronization signal detection circuit 28. When the count value returns to an initial value (zero), the buffer sector counter 53 generates a buffering stop pulse signal.

The buffer trigger generation circuit 54 instructs the buffering to be started when the buffering start pulse signal goes high. Further, the buffer trigger generation circuit 54 instructs the buffering to be stopped when the buffering stop pulse signal goes high.

The target address register 51, the comparison circuit 52, the buffer sector counter 53, and the buffer trigger generation circuit 54 automatically start and stop buffering in response to a transfer request from a host computer.

The error check circuit ECB includes an error correction detection circuit 17 and a check sector counter 61.

The error correction detection circuit 17 corrects and detects errors in the CD-ROM data written to the buffer RAM 6. The error correction detection circuit 17 receives the CD-ROM data and sector information in single sector units from the buffer RAM 6, determines the process to be carried out on the CD-ROM data based on the sector information, corrects code errors with the ECC, and detects code errors with the EDC. For example, if the sector information is in mode 1 or in form 1 of mode 2, error correction and error detection are performed. If the sector information is form 2 of mode 2, only error detection is performed. The CD-ROM data that has undergone a predetermined process is stored again in the buffer RAM 6 to be transferred to the host computer. The error correction detection circuit 17 provides a check head register 62 with the address information of a head selector, which has been checked for errors and has been stored in the buffer RAM 6.

In response to a timing signal, the check sector counter 61 counts the number of sectors that have undergone a predetermined error check in the error correction detection circuit 17 and provides the count value to a command decision circuit 26.

The data transfer circuit DTB includes a read address generation circuit 20, the address register 21, an address counter 22, a sector information read register 23, a sector information decision circuit 24, a command register 25, the command decision circuit 26, a transfer buffer 27, and the check head register 62. The read address generation circuit 20, the address register 21, the sector information decision circuit 24, and the command decision circuit 26 configure a data transfer circuit. The data transfer circuit checks the flag bits of the transfer request command stored in the command register 25 and determines the data transfer byte number per sector and transfers data in correspondence with the data transfer byte number to the host computer.

In response to instructions from the sector information decision circuit 24 and the command decision circuit 26, the read address generation circuit 20 generates addresses designating the first and second sections of the buffer RAM 6. Based on the address, the sector information and the CD-ROM data (user data) are read from the buffer RAM 6. The read sector information is temporarily stored in the sector information read register 23. The read user data is provided to the transfer buffer 27 via the first data bus 18, and the user data is transferred to the host computer from the transfer buffer 27.

The address register 21 receives from the write address generation circuit 16 the write address corresponding to the data at the head of each sector and the write address corresponding to the sector information. Simultaneously, among the plural pieces of sector time information stored in the buffer RAM 6, the address register 21 stores the smallest piece of time information or the largest piece of time information. This enables recognition of the time information of all of the sectors stored in the buffer RAM 6.

The address counter 22 increments its count value each time the read address generation circuit 20 updates the read address and provides the count value to the command decision circuit 26. The address counter 22 is operated when the read address generation circuit 20 provides the read address to the buffer RAM 6 and counts the sector number (or the byte number) of the data read from the buffer RAM 6.

The check head register 62 stores the address of the head sector checked by the error correction detection circuit 17 and stored in the buffer RAM 6.

The sector information decision circuit 24 determines the format of the CD-ROM data of the sector corresponding to the sector information based on the sector information stored in the sector information read register 23. The sector information decision circuit 24 sets an offset value added to the read address by the read address generation circuit 20 in accordance with the format of the CD-ROM data when transferring data to the host computer. In other words, user data excluding the header and the sub-header is transferred to the host computer. Thus, in accordance with the format of each sector, the addresses of the header and the sub-header are added to the head address as an offset value. When all of the CD-ROM data (2,352 bytes) in a sector is transferred, offsetting is not necessary. The command decision circuit 26 determines whether offsetting is necessary based on the instruction from the host computer.

The sector information decision circuit 24 is provided with the sector information included in the transfer request command from the host computer via the command register 25. Further, the sector information decision circuit 24 determines whether the sector information generated by the sector information conversion circuit 14 matches the sector information of the transfer request command (flag bits indicating the sector format). The sector information decision circuit 24 sets the offset value if the two pieces of information match, and notifies the microcomputer 70 of an error if the two pieces of information do not match.

The command register 25 temporarily stores the transfer request command provided from the host computer. Referring to FIG. 6, the transfer request command includes 12 bytes. The flag bits indicating the format of the sector are set in the second, third, and fourth bits of the first byte. A logic address LBA of the head sector of the transfer request data is set in the third, fourth, and fifth bytes. The transfer request sector number (transfer block number) TBL is set in the sixth, seventh, and eighth bytes.

The command decision circuit 26 sends operating instructions to the read address generation circuit 20 and the sector information read register 23 based on the address of the head data of each sector stored in the address register 21, the count value of the address counter 22, and the transfer request command stored in the command register 25. Based on the information of the check sector counter 61 and the check head register 62, the command decision circuit 26 determines whether the data corresponding to the transfer request of the host computer has been checked for errors and stored in the buffer RAM 6. The command decision circuit 26 sends operating instructions to the read address generation circuit 20 and the sector information read register 23 when the transfer request data is stored in the buffer RAM 6 to automatically transfer data to the host computer.

The transfer buffer 27 receives user data read from the buffer RAM 6 via the first data bus 18 and transfers the user data to the host computer. The transfer buffer 27 is connected to the transfer sector counter 42. The transfer sector counter 42 counts the sector number of the user data transferred to the host computer and provides the count value CT to the buffering control circuit 43.

The timing adjustment circuit TCB includes the synchronization signal detection circuit 28 and a timing generation circuit 29. The synchronization signal detection circuit 28 detects 12 bytes of the synchronization signal at the head of each sector of the CD-ROM data and provides the timing generation circuit 29 with a timing signal indicating the beginning of a sector. The synchronization signal detection circuit 28 provides error detection data to the microcomputer 70 via the second data bus 19 when the synchronization signal is not detected.

The timing generation circuit 29 receives the timing signal from the synchronization signal detection circuit 28 and generates various timing clock signals for determining the operating timing of the microcomputer 70, the data write circuit DWB, the error check circuit ECB, and the data transfer circuit DTB.

In the CD-ROM decoder 200, the data write circuit DWB and the data transfer circuit DTB are operated in accordance with the timing clock signal, the flag bits of the transfer request command from the host computer is recognized, and the transfer byte number per sector is determined from the format of the transfer sector. Accordingly, the transfer of CD-ROM data is performed automatically and not controlled by the microcomputer 70.

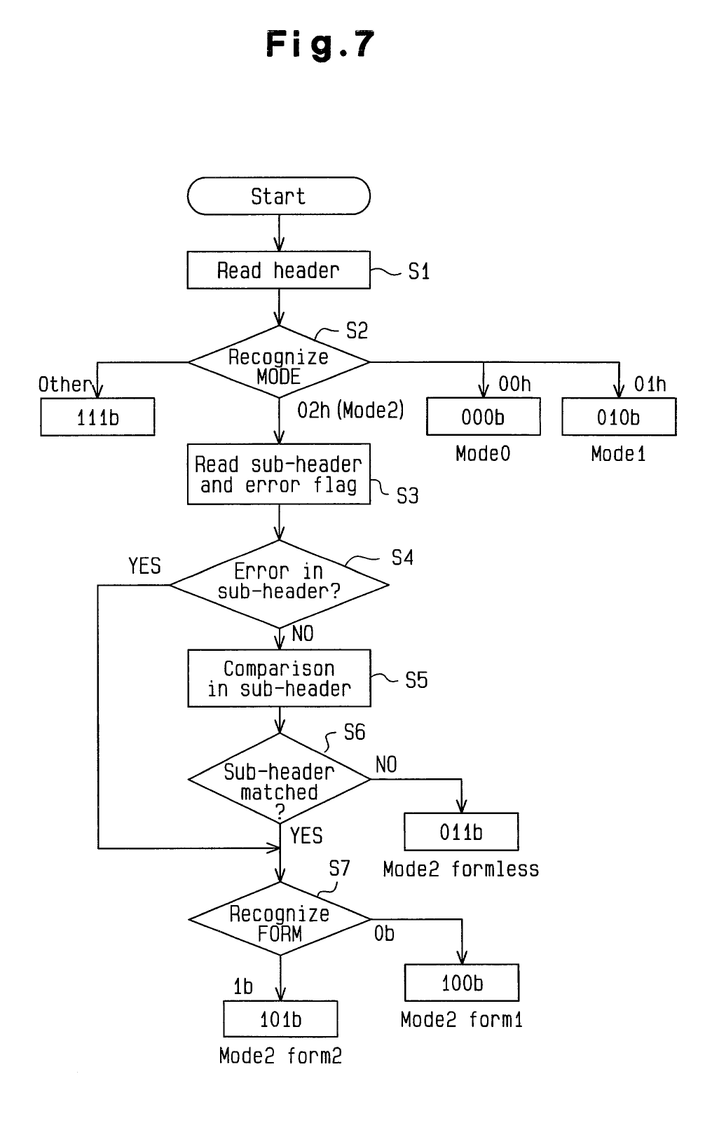

Before describing the automatic transfer of data, an operation for determining the sector information (data format) will be discussed with reference to the flowchart of FIG. 7.

The sector information conversion circuit 14 determines the sector information based on the information of the header, the sub-header, and the error flag of the sub-header. The timing generation circuit 29 adjusts the processing timing of the sector information conversion circuit 14. The sector information conversion circuit 14 includes a comparison circuit (not shown) used to detect the matching of data and a logic circuit (not shown), such as an AND circuit.

Referring to FIG. 7, at step S1, the header information register 13 provides the sector information conversion circuit 14 with the header information of the CD-ROM data.

At step S2, the sector information conversion circuit 14 recognizes the mode identification code of the header. For example, if the 1-byte mode identification code is “00h” (h indicating a hexadecimal), the sector information conversion circuit 14 sets the sector information to “000b” (b indicating a binary), which indicates mode 0. If the mode identification code is “01h”, the sector information is set to “010b”, which indicates mode 1.

If the mode identification code is “02h”, the sector information conversion circuit 14 determines that the mode is mode 2 and then proceeds to step S3. If the mode identification code is not “00h”, “01h”, or “02h”, the sector information conversion circuit 14 sets the sector information to “111b”.

At step S3, the header information register 13 provides the sector information conversion circuit 14 with the sub-header, which follows the header. Further, the sector information conversion circuit 14 is provided with the error flag of the sub-header from the error flag register 30.

At step S4, the sector information conversion circuit 14 determines whether there is an error flag in any one of the bytes of the sub-header (8 bytes). If the sub-headers include an error flag, the sector information conversion circuit 14 proceeds to step S7 and recognizes the form of mode 2 (form 1 or form 2). The determination of step S7 is performed to prevent the form of mode 2 from being erroneously recognized as formless.

When determining that the bytes of the sub-header does not include an error flag, the sector information conversion circuit 14 proceeds to step S5.

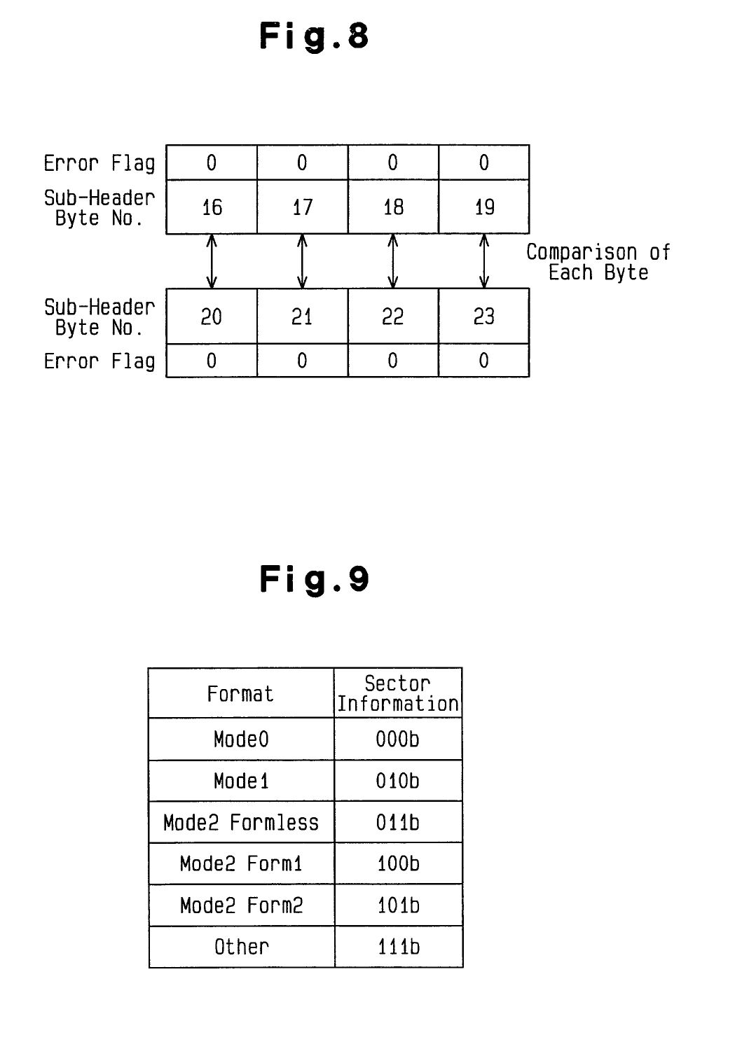

Referring to FIG. 8, at step 5, the 8 bytes of the sub-header are divided into former 4 bytes (16th to 19th bytes) and latter 4 bytes (20th to 23rd bytes). The sector information conversion circuit 14 compares the former 4 bytes to the latter 4 byes in bit units.

At step S6, the sector information conversion circuit 14 determines whether the former 4 bytes match the latter 4 bytes. Normally, the former 4 bytes match the latter 4 bytes in the sub-header. Accordingly, the sub-header is detected by detecting whether its former half and latter half are matched. When mode 2 is formless, user data exists at a location corresponding to the sub-header. In this case, the sector information conversion circuit 14 does not detect the sub-header and sets the sector information to “011b”, which indicates the formless.

If the sub-header is detected, the sector information conversion circuit 14 proceeds to step S7 and recognizes the form. A predetermined bit of the sub-header indicates form information. Thus, if the predetermined bit is “0b”, the sector information is set to “100b”, which indicates form 1 of mode 1, and if the predetermined bit is “1b”, the sector information is set to “101b”, which indicates form 2 of mode 2.

The sector information, which is 3 bits of binary data (FIG. 9) is generated through the above processing. A fixed value of 5 bits is added to the sector information, and the sector information of one byte is stored in the second section of the buffer RAM 6. The fixed value may be information other than the sector information.

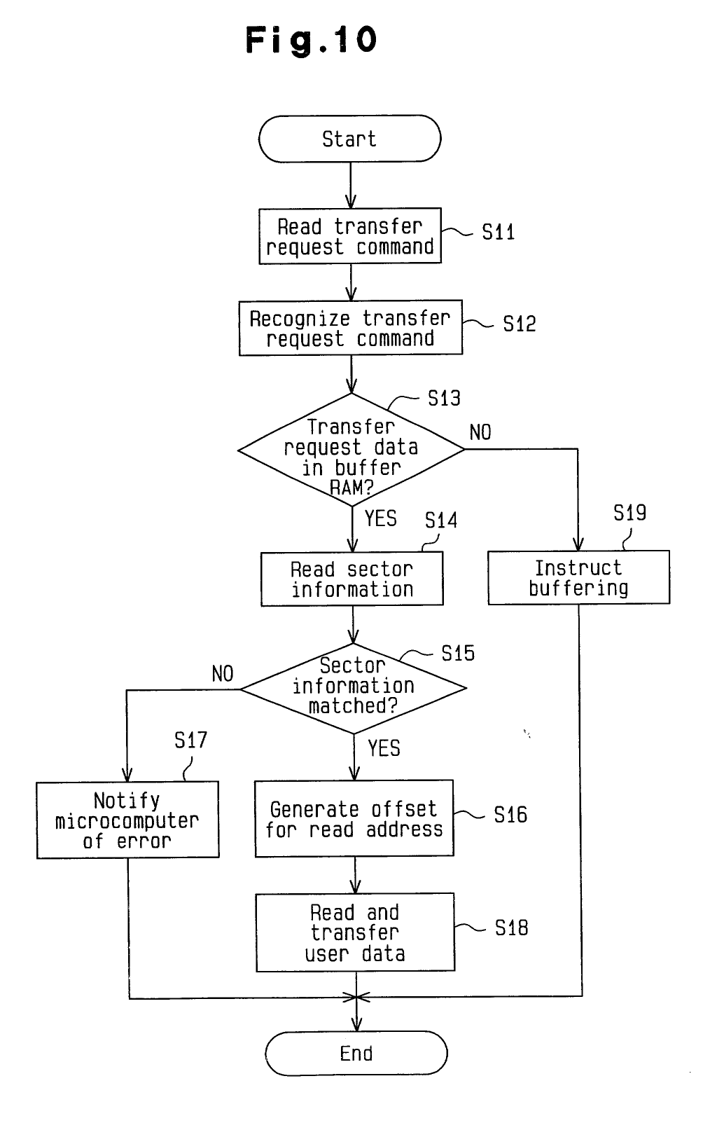

The automatic transfer of the requested sector based on the sector information (sector format information) will now be discussed with reference to the flowchart of FIG. 10. During the automatic transfer, the format of the transfer request sector and the number of transfer bytes are recognized from the transfer request command. The command decision circuit 26 and the sector information decision circuit 24 include known logic circuits, such as a comparison circuit (not shown) for comparing data or an adding circuit for adding data (not shown).

At step S11, the host computer stores a transfer request command, such as that shown in FIG. 6, in the command register 25. The command register 25 then provides the transfer request command to the command decision circuit 26.

At step S12, the command decision circuit 26 recognizes the head sector address from the transfer request command flag bits (in FIG. 6, each bit of the third to fifth bytes).

Then, at step S13, the command decision circuit 26 refers to the address and time information stored in the address register 21 or the check head register 62 and determines whether the requested sector (target sector) is stored in the buffer RAM 6. If the target sector is stored in the buffer RAM 6, the command decision circuit 26 proceeds to step S14 and instructs the read address generation circuit 20 to generate an address for reading the sector information from the buffer RAM 6. Based on the address of the read address generation circuit 20, the sector information of the target sector is read from the buffer RAM 6 and the sector information is stored in the sector information read register 23.

At step S15, the sector information decision circuit 24 recognizes the format of the target sector based on the sector information. Further, the sector information decision circuit 24 determines whether the sector information (in FIG. 9, the sector format) matches the flag bits (in FIG. 6, the 5th to 7th bits of the first byte) indicating the sector format of the transfer request command. If the sector information matches the format, the sector information decision circuit 24 proceeds to step S16 and generates offset information based on the format. The sector information decision circuit 24 then provides the offset information to the read address generation circuit 20. The offset information is generated when the host computer requests for the transfer of only user data. At step S15, if the sector information decision circuit 24 determines that the sector information and the flag bits of the transfer request command do not match, the sector information decision circuit 24 proceeds to step S17 and notifies the microcomputer 70 of an error.

At step S18, the read address generation circuit 20 adds the offset information to the head address of the read sector to generate an address signal and provides the address signal to the buffer RAM 6 to read the user data of the target sector from the buffer RAM 6. For example, if the target sector is in mode 1, the user data of the target sector is read from the address obtained by adding the 12 byes of the synchronization signal and the 4 bytes of the header to the head address stored in the address register 21. The number of transfer bytes per sector is automatically recognized in this manner in accordance with the format of each sector.

When the reading of the user data starts, the address counter 22 counts the byte number of user data read from the buffer RAM 6. When the byte number of the read user data reaches the byte number instructed by the host computer, the command decision circuit 26 instructs the read address generation circuit 20 to stop reading data.

In this manner, the data stored in the buffer RAM 6 is automatically transferred to the host computer without being controlled by the microcomputer.

At step S13, if the command decision circuit 26 determines that the CD-ROM data of the target sector is not stored in the buffer RAM 6, the command decision circuit 26 proceeds to step S19 and sends a new CD-ROM data read (buffering) instruction to the microcomputer 70 via the second data bus 19. Based on the instruction, the microcomputer 70 activates the pickup 2 and reads the CD-ROM data of multiple sectors including the target sector from the disc 1. When the CD-ROM data including the target sector is stored in the buffer RAM 6, the above automatic transfer process is performed.

The advantages of the CD-ROM decoder 200 according to the preferred and illustrated embodiment are discussed below.

(1) In the preferred embodiment, the data transfer circuit DTB performs the CD-ROM data transfer control that was performed by the prior art microcomputer 7. This decreases the number of controls and processing that were performed by the microcomputer 70, such as the recognition of flag bits. Thus, the load on the microcomputer 70 decreases and the speed and number of transferred bytes in the microcomputer 70 increase.

(2) Since the flag bits of the transfer request command is automatically recognized, the time period from when the CD-ROM decoder 200 receives a command to when data is transferred to the host computer is shortened. This improves the performance of the decoder 200.

(3) The sector information is temporarily stored in the buffer RAM 6. Thus, the CD-ROM decider 200 does not require a means for storing sector information. The sector information is temporarily stored in the buffer memory 6 with the CD-ROM data. Thus, sector information is properly processed in association with the CD-ROM data.

(4) If the sector information and the flag bits of the transfer request command do not match, the microcomputer 70 is notified of an error. This enables the microcomputer 70 to readily cope with such error.

(5) The sector information is determined by referring to the error flag stored in the error flag register 30. This improves the reliability of the sector information. Based on the sector information, the number of transferred bytes per sector is automatically recognized based on the format of each sector. This improves the reliability of the transferred data.

It should be apparent to those skilled in the art that the present invention may be embodied in many other specific forms without departing from the spirit or scope of the invention. Particularly, it should be understood that the present invention may be embodied in the following forms.

The notification of an error to the microcomputer when the sector information and the flag bits of the transfer request command do not match may be omitted.

The process for setting the sector information based on the error flag stored in the error flag register 30 may be omitted.

The sector information write register 15 need not be provided. For example, the sector information may be transferred from the sector information conversion circuit 14 to the microcomputer 70. Alternatively, a memory may be provided to store the sector information. Such configurations also reduce the load resulting from the transfer of CD-ROM data in the microcomputer 70.

If an error flag is included in any one of the sub-headers when setting the data format, the comparison of the sub-header may be performed by the bytes other that including the error flag.

The buffer sector counter 53 may function as an up-counter that generates a buffering stop pulse signal when the count value reaches the buffering request sector number.

The present examples and embodiments are to be considered as illustrative and not restrictive, and the invention is not to be limited to the details given herein, but may be modified within the scope and equivalence of the appended claims.

What is claimed is:

1. A CD-ROM decoder for temporarily storing in a buffer memory in sector units digital data having a predetermined number of bytes and a predetermined format, processing the digital data by correcting and detecting code errors included in the digital data, and transferring the processed digital data, the CD-ROM decoder comprising:
a command register for storing a data transfer request command that includes flag bits as format information of transfer request data; and
a data transfer circuit connected to the command register for deciding the flag bits of the data transfer request command and determining the byte number of the processed digital data that is to be transferred per sector, wherein the data transfer circuit reads the processed digital data from the buffer memory based on the determined byte number and transfers the read processed digital data.

2. The CD-ROM decoder according to claim 1, wherein the digital data includes header information and sub-header information, the CD-ROM decoder further comprising:
a header information register for storing the header information and the sub-header information; and
a sector information conversion circuit connected to the header information register for deciding the format of the digital data in each sector based on the header information and the sub-header information and generating sector information indicating the decided format, the sector information conversion circuit temporarily storing the sector information in the buffer memory in association with the digital data, wherein the data transfer circuit receives the sector information from the buffer memory, compares the sector information to the flag bits of the transfer request command, and determines the transfer byte number of the processed digital data that is to be transferred per sector based on the flag bits when the sector information and the flag bits match.

3. The CD-ROM decoder according to claim 2, wherein the data transfer circuit issues error information when the sector information and the flag bits do not match.

4. The CD-ROM decoder according to claim 2, wherein the transfer request command includes first address information of the buffer memory for the processed digital data that is to be transferred, the data transfer circuit including:
an address register for storing in sector units second address information of the digital data stored in the buffer memory;
a read address generation circuit for generating a read address of the digital data stored in the buffer memory based on the determined transfer byte number; and
a command decision circuit connected to the address register and the read address generation circuit for comparing the first address information of the transfer request command to the second address information stored in the address register and deciding based on the comparison whether the processed digital data that is to be transferred is stored in the buffer memory, wherein the command decision circuit sends to the read address generation circuit a command for reading the processed digital data when the digital data that is to be transferred is stored in the buffer memory.

5. The CD-ROM decoder according to claim 4, wherein the data transfer circuit includes:
a sector information decision circuit connected to the read address generation circuit for deciding the flag bits of the data transfer request command and setting an offset address based on the decided format, wherein the read address generation circuit adds the offset address to a head address of a sector of the digital data to generate the read address of the digital data.

6. A CD-ROM decoder for temporarily storing in a buffer memory in sector units digital data having a predetermined number of bytes and a predetermined format, processing the digital data by correcting and detecting code errors included in the digital data, and transferring the processed digital data, wherein the digital data includes header information and sub-header information, the CD-ROM decoder comprising:
a sector information conversion circuit for deciding the format of the digital data in each sector based on the header information and the sub-header information and generating sector information indicating the decided format, the sector information conversion circuit temporarily storing the sector information in the buffer memory in association with the digital data;
a command register for storing a data transfer request command that includes flag bits as format information of transfer request data, wherein the transfer request command includes first address information of the buffer memory for the processed digital data that is to be transferred;
a sector information decision circuit for receiving the sector information from the buffer memory and the transfer request command from the command register and comparing the sector information to the flag bits of the transfer request command, wherein the sector information decision circuit determines a transfer byte number of the processed digital data that is to be transferred per sector based on the flag bits when the sector information and the flag bits match;
an address register for storing in sector units second address information of the digital data stored in the buffer memory;
a read address generation circuit for generating the read address of the digital data stored in the buffer memory based on the determined transfer byte number; and
a command decision circuit connected to the address register and the read address generation circuit for comparing the first address information of the transfer request command to the second address information stored in the address register and determining based on the comparison whether the processed digital data that is to be transferred is stored in the buffer memory, wherein the command decision circuit sends to the read address generation circuit a command for reading the processed digital data when the digital data that is to be transferred is stored in the buffer memory.

7. A method for transferring in sector units digital data having a predetermined number of bytes and a predetermined format with a CD-ROM decoder, wherein the CD-ROM decoder includes a data transfer circuit, the method comprising the steps of:
temporarily storing the digital data in a buffer memory;
processing the digital data by correcting and detecting code errors included in the digital data;
storing a data transfer request command that includes format information of transfer request data in a command register;
deciding the format information of the data transfer request command and determining the byte number of the processed digital data that is to be transferred per sector with the data transfer circuit; and
reading the processed digital data from the buffer memory based on the determined byte number and transferring the read processed digital data with the data transfer circuit.
